(19) United States
(12) Patent Application Publication
(10) Pub. No.: US 2011/0073173 A1
(43) Pub. Date: Mar. 31, 2011

(54) SOLAR CELL AND METHOD FOR MANUFACTURING THE SAME

(75) Inventor: Sung-Ho HWANG, Seoul (KR)

(73) Assignee: SAMSUNG ELECTRONICS CO., LTD., Suwon-si (KR)

(21) Appl. No.: 12/727,454

(22) Filed: Mar. 19, 2010

(30) Foreign Application Priority Data
Sep. 29, 2009 (KR) 10-2009-0092428

(51) Int. Cl. H01L 31/0352; H01L 31/18; H01L 21/265

(52) U.S. Cl. 136/255; 438/57; 438/514; 257/E31.033; 257/E21.334

(57) ABSTRACT

A solar cell including a first semiconductor layer including a first impurity, a second semiconductor layer disposed on the first semiconductor layer, the second semiconductor layer including a second impurity, a first electrode electrically connected to the first semiconductor layer, and a second electrode electrically connected to the second semiconductor layer, wherein the first semiconductor layer includes a plurality of impurity-doped regions including a third impurity, wherein a type of the third impurity is the same as a type of the second impurity.

This application claims priority to Korean Patent Application No. 10-2009-0092428, filed on Sep. 29, 2009, and all the benefits accruing therefrom under 35 U.S.C. §119, the content of which in its entirety is herein incorporated by reference.

### BACKGROUND OF THE INVENTION

1. Field of the Invention

This disclosure relates to a solar cell and a method of manufacturing the same.

2. Description of the Related Art

A solar cell is a photoelectric conversion device that transforms solar energy into electrical energy. Solar cells have attracted much attention as a pollution-free next generation energy source.

A solar cell produces electrical energy by transferring electrons and holes to n-type and p-type semiconductors, respectively, and then collecting the electrons and the holes in electrodes when an electron-hole pair (“EHP”) is produced by solar light energy absorption in a photoactive layer, which is inside the semiconductors.

In order to improve the production of electrical energy by a solar cell, the collection efficiency of light which is incident on a solar cell is desirably improved. Furthermore, silicon, such as a silicon substrate, has a low absorption efficiency for long wavelength light, specifically light having a wavelength of equal to or greater than about 1000 nanometers, due to the energy band gap of silicon. Accordingly, materials which provide improved absorption and conversion of long wavelength light are being actively researched.

### BRIEF SUMMARY OF THE INVENTION

One aspect of this disclosure provides a solar cell that effectively traps long wavelength light to prevent light loss.

Another aspect of this disclosure provides a method of manufacturing the solar cell.

According to one aspect of this disclosure, provided is an exemplary embodiment of a solar cell that includes a first semiconductor layer including a first impurity; a second semiconductor layer disposed on the first semiconductor layer, the second semiconductor layer including a second impurity; a first electrode electrically connected to the first semiconductor layer; and a second electrode electrically connected to the second semiconductor layer, wherein the first semiconductor layer includes a plurality of impurity-doped regions including a third impurity, wherein a type of the third impurity is the same as a type of the second impurity.

In one exemplary embodiment, the plurality of impurity-doped regions may be discontinuously disposed.

In one exemplary embodiment, the plurality of impurity-doped regions may be disposed in substantially a same plane as each other.

In one exemplary embodiment, the plurality of impurity-doped regions may include a quantum well, a quantum wire, a quantum dot, or a combination comprising at least one of the foregoing.

In one exemplary embodiment, each impurity-doped region of the plurality of impurity-doped regions may have a dimension of about 8 nanometers to about 150 nanometers.

In one exemplary embodiment, the first semiconductor layer may have a first surface contacting the second semiconductor layer and a second surface disposed opposite the first surface, and the plurality of impurity-doped regions may be disposed within a distance of about 10 micrometers from the second surface of the semiconductor layer.

In one exemplary embodiment, the plurality of impurity-doped regions may be disposed at a distance of about 3 micrometers to about 4 micrometers from the surface of the second side of the first semiconductor layer.

In one exemplary embodiment, the plurality of impurity-doped regions may absorb light having a wavelength of equal to or greater than about 1000 nanometers.

In one exemplary embodiment, the first impurity may be a p-type impurity, and the second impurity may be an n-type impurity.

In one exemplary embodiment, the second impurity comprises the same type of material as the third impurity.

According to another exemplary embodiment of the disclosure, a method of manufacturing a solar cell includes providing a first semiconductor layer including a first impurity; providing a second semiconductor layer disposed on the first semiconductor layer and including a second impurity; providing a plurality of impurity-doped regions including a third impurity in a portion of the first semiconductor layer, wherein a type of the third impurity is the same as a type of the second impurity; providing a first electrode electrically connected to the first semiconductor layer; and providing a second electrode electrically connected to the second semiconductor layer.

In one exemplary embodiment, the providing a plurality of impurity-doped regions may be performed by ion implantation.

In one exemplary embodiment, the providing a plurality of impurity-doped regions may include providing a photosensitive layer having a plurality of openings on a surface of the first semiconductor layer, and ion implanting the third impurity while using the photosensitive layer as a mask.

In one exemplary embodiment, the ion implantation may dispose the third impurity within a distance of about 10 micrometers from the surface of the first semiconductor layer.

In one exemplary embodiment, the ion implantation may dispose the third impurity at a distance of about 3 micrometers to about 4 micrometers from a surface of the first semiconductor layer.

In one exemplary embodiment, the openings of the photosensitive layer may have a dimension of about 8 nanometers to about 150 nanometers.

In one exemplary embodiment, the first impurity may be a p-type impurity, and the second impurity may be an n-type impurity.

### BRIEF DESCRIPTION OF THE DRAWINGS

The above and other aspects, advantages and features of this disclosure will become more apparent by describing in further detail exemplary embodiments thereof with reference to the accompanying drawings in which:

FIG. 1 is a cross-sectional view of an exemplary embodiment of a solar cell;

FIG. 2 is a schematic diagram showing an exemplary embodiment of an energy level of an impurity doped region of the exemplary embodiment of a solar cell of FIG. 1; and

FIGS. 3 to 6 are cross-sectional views showing an exemplary embodiment of sequential processes of manufacturing the exemplary embodiment of a solar cell of FIG. 1.

### DETAILED DESCRIPTION OF THE INVENTION

Exemplary embodiments of this disclosure will hereinafter be described in further detail referring to the following accompanied drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout. Thus, the disclosed embodiments are exemplary, and this disclosure is not limited thereto.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom,” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

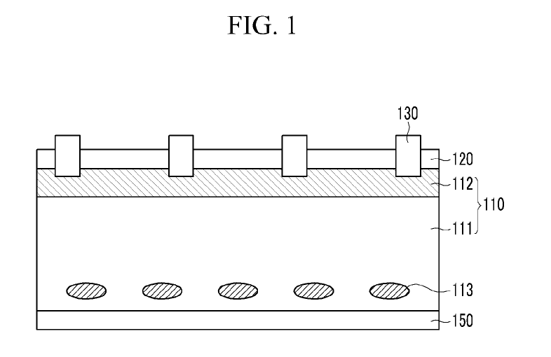

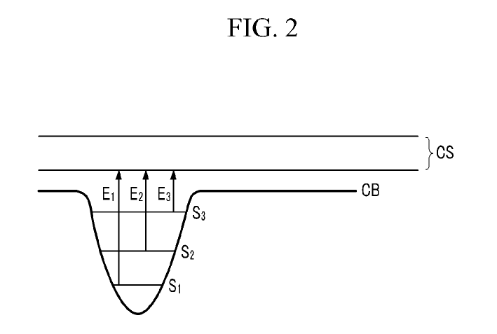

Hereinafter, an exemplary embodiment of a solar cell according to this disclosure is described with reference to FIG. 1 and FIG. 2.

FIG. 1 is a cross-sectional view of an exemplary embodiment of a solar cell, and FIG. 2 is a schematic diagram showing an energy level of an impurity-doped region of the exemplary embodiment of a solar cell of FIG. 1.

Hereinafter, for the better understanding and ease of description, upper and lower positional relationships are described with respect to a semiconductor substrate 110, but the disclosure is not limited thereto. In addition, a “front side” refers to a side receiving solar energy and a “rear side” refers to a side opposite to the front side.

As shown in FIG. 1, the semiconductor substrate 110 includes a lower semiconductor layer 111 and an upper semiconductor layer 112. The lower semiconductor layer 111 is disposed at the rear side, and the upper semiconductor layer 112 is disposed at the front side.

The semiconductor substrate 110 may include crystalline silicon, and may be, for example, a silicon wafer. The lower semiconductor layer 111 may include a semiconductor layer doped with the first impurity, and the upper semiconductor layer 112 may include a semiconductor layer doped with the second impurity, wherein the type of the second impurity is different from the type of the first impurity. The first impurity may be a p-type impurity, which is a Group III element such as boron (B), and the second impurity may be an n-type impurity, which is a Group V element, such as phosphorus (P).

The lower semiconductor layer 111 further includes a plurality of impurity-doped regions 113 including a third impurity, wherein the third impurity may be of the same type as the second impurity. In an embodiment, the third impurity may be the same as the second impurity. The plurality of impurity-doped regions 113 are disposed near the rear side of semiconductor substrate 110 and are discontinuously disposed on substantially a same plane.

The plurality of impurity-doped regions 113 may be disposed within a distance of about 10 micrometers (μm), specifically about 0.1 μm to about 9 μm, more specifically about 1 μm to about 8 μm from the surface of the rear side of the lower semiconductor layer 111. In an embodiment, the impurity-doped regions may be disposed about 3 μm to about 4 μm from the surface of the rear side of lower semiconductor layer 111.

The plurality of impurity-doped regions 113 may be quantum wells, quantum wires, or quantum dots, and have a size of about 8 nanometers (nm) to about 150 nm in their largest dimension, specifically about 10 nm to about 125 nm, more specifically about 12 nm to about 100 nm. In an exemplary embodiment, size refers to an average largest diameter.

The quantum wells have a substantially two-dimensional structure, the quantum wires have a substantially one-dimensional structure; and the quantum dots have a substantially spherical structure.

FIG. 2 shows an energy band diagram of a nano-size impurity-doped region 113.

Referring to FIG. 2, the energy band diagram includes a conduction band (“CB”) and a continuous state (“CS”). A nano-size impurity-doped region 113 has an energy band which is confined by a width of the impurity-doped region 113, wherein the width is a dimension of several to several tens of nm, specifically about 1 nm to about 50 nm, more specifically about 3 to about 30 nm. In an embodiment, the width is a dimension in a direction perpendicular to a surface of the first semiconductor layer. The energy band may have a plurality of energy levels, including a first energy level S₁, a second energy level S₂, and a third energy lever S₃.

The energy difference between each of the first to third energy levels S₁, S₂, and S₃ is less than the band gap of silicon. Accordingly, the impurity-doped region effectively absorbs light having a long wavelength, such as light having a wavelength of equal to or greater than about 1000 nm, specifically equal to or greater than 1100 nm, more specifically equal to or greater than 1200 nm. When the impurity-doped region 113 absorbs light of a long wavelength, the electrons present in each of the first to third energy levels (S₁, S₂, and S₃) may adsorb energy (specifically first to third energies E1, E2, and E3, respectively) to excite the electrons in to the continuous state CS.

The intraband absorption in the impurity-doped region 113 is better for long wavelength absorption than the inter-band absorption from the valence band to the conduction band, thereby improving absorption of long wavelength light.

In another exemplary embodiment, the plurality of impurity-doped regions 113 may be discontinuously disposed. When the impurity-doped regions 113 are continuously disposed, the electric charges generated in the lower semiconductor layer 111 may not effectively migrate to the rear side of the semiconductor substrate 110, making accumulation of electric charges in the rear electrode difficult. According to an embodiment, it is possible to absorb long wavelength light without interrupting the transport of electric charge generated in the lower semiconductor layer 111 by disposing the plurality of impurity-doped regions 113 discontinuously.

The semiconductor substrate 110 may have a textured surface. The semiconductor substrate 110 with the textured surface may have protrusions and depressions, which may have a pyramidal shape, or the semiconductor substrate 110 may include a porous structure, such as a honeycomb structure. The semiconductor 110 with the textured surface may effectively increase the amount of light absorbed into a solar cell by increasing light scattering and thereby lengthening a light transfer path while reducing reflectance of incident light.

A dielectric layer 120 may be disposed on the semiconductor substrate 110.

The dielectric layer 120 may include an insulating material which is capable of absorbing less light, and for example, the dielectric layer 120 may include silicon nitride (SiNₓ), silicon oxide (SiO₂), titanium oxide (TiO₂), aluminum oxide (Al₂O₃), magnesium oxide (MgO), cerium oxide (CeO₂), or a combination comprising at least one of the foregoing. The dielectric layer 120 may include a single layer or a plurality of layers. The dielectric layer 120 may have a thickness of, for example, about 200 angstroms (Å) to about 1500 Å, specifically 300 Å to about 1400 Å, more specifically 400 Å to about 1300 Å.

The dielectric layer 120 may act as an anti-reflective coating (“ARC”) for decreasing the light reflectivity, increasing the selectivity for the selected wavelength region, and simultaneously improving the contacting characteristic with silicon at the surface of the semiconductor substrate 110 to increase the efficiency of the solar cell.

A plurality of front electrodes 130 are formed (e.g., disposed) on at least one surface of the dielectric layer 120. The front electrodes 130 extend along one direction of the substrate in parallel, and penetrate the dielectric layer 120 to contact the upper semiconductor layer 112. The front electrodes 130 may include a low resistivity metal such as silver (Ag), and may be designed into the grid pattern considering shadowing loss and sheet resistance.

A front electrode bus bar (not shown) is formed (e.g., disposed) on the front electrodes 130. The front electrode bus bar connects adjacent solar cells when a plurality of solar cells are assembled.

A dielectric layer (not shown) is formed (e.g., disposed) on the rear side of the semiconductor substrate 110. The dielectric layer may include silicon oxide (SiO₂), silicon nitride (SiNₓ), aluminum oxide (Al₂O₃), or the like, or a combination comprising at least one of the foregoing, and may substantially reduce or effectively prevent recombination of charges and simultaneously prevent leakage of current to increase the efficiency of the solar cell.

A rear electrode 150 is formed (e.g., disposed) on one surface of the dielectric layer.

The rear electrode 150 may include an opaque metal such as aluminum (Al) and is formed (e.g., disposed) on the front side of the dielectric layer to reflect light which passes through the semiconductor substrate 110 to the semiconductor substrate, to substantially reduce or effectively prevent the leakage of light and to increase the efficiency. The rear electrode 150 penetrates the dielectric layer and electrically connects to the lower semiconductor layer 111.

Hereinafter, a method of manufacturing a solar cell according to another embodiment of this disclosure is described with reference to FIG. 3 to FIG. 6 and FIG. 1.

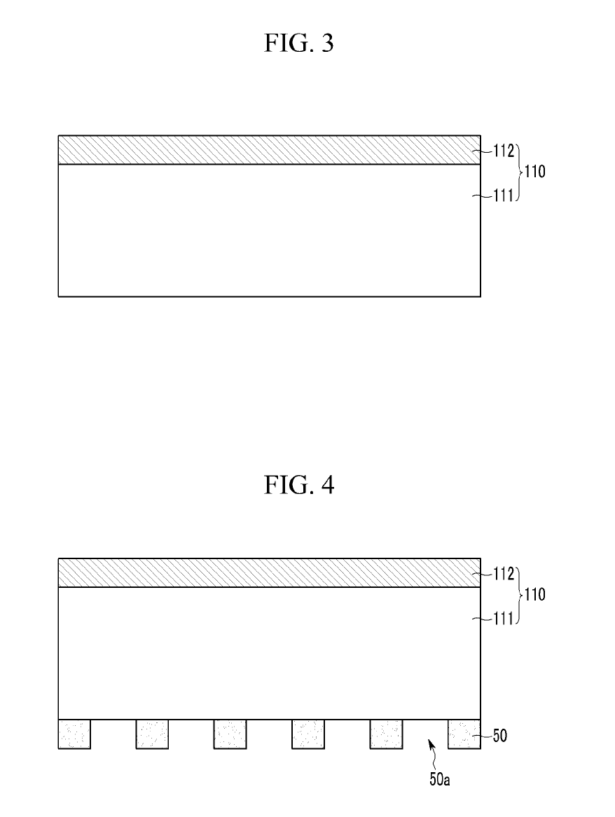

FIGS. 3 to 6 are cross-sectional views showing a sequential process of manufacturing the solar cell of FIG. 1.

First, a semiconductor substrate 110, such as a silicon wafer, is prepared. The semiconductor substrate 110 may be doped with a first impurity, which may be, for example, a p-type impurity.

Then, the semiconductor substrate 110 is subjected to surface texturing. The surface texturing may be performed in accordance with a wet method using a strong acid, such as an acid comprising nitric acid and fluoric acid, or a strong basic solution, such as a solution of sodium hydroxide, or a dry method using a plasma, for example.

Then, a portion of the semiconductor substrate 110 is doped with a second impurity, which may be, for example, an n-type impurity. The n-type impurity may be doped by diffusing POCl₃, H₃PO₄, or the like, or a combination comprising at least one of the foregoing, into a portion of the semiconductor substrate 110 at a high temperature. Accordingly, as shown in FIG. 3, the semiconductor substrate 110 includes a lower semiconductor layer 111 and an upper semiconductor layer 112, which are doped with different impurities. In an embodiment, the lower semiconductor layer 111 and the upper semiconductor layer 112 are doped with a first impurity and a second impurity, respectively.

As shown in FIG. 4, a photosensitive layer (not shown) is coated (e.g., disposed) on the rear side of semiconductor substrate 110 and patterned to provide a photosensitive pattern 50 having a plurality of openings 50a.

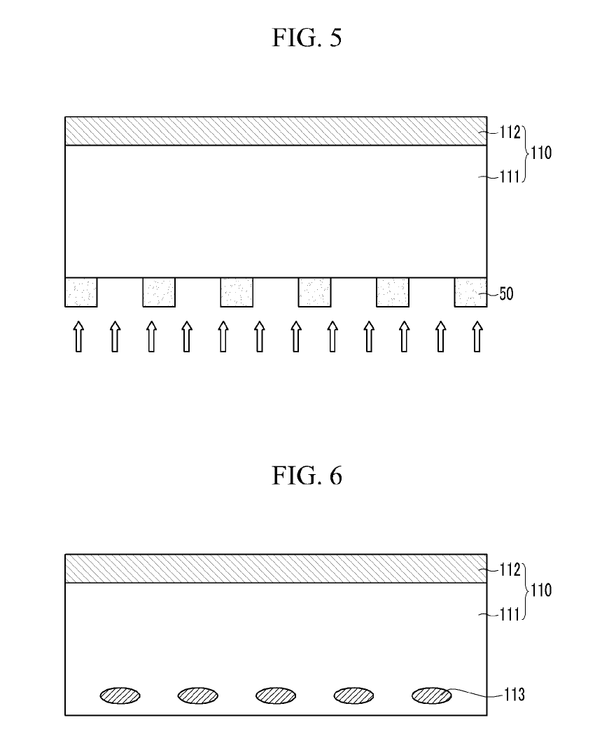

Referring to FIG. 5, a third impurity, which may also be an n-type impurity, is implanted into the rear side of the semiconductor substrate 110 using the photosensitive pattern 50 as a mask. The third impurity may include phosphorous, arsenic, antimony, or a combination comprising at least one of the foregoing. The third impurity may be implanted by ion implantation. The ion implantation may use an ion beam having an energy of several tens to several hundreds of kiloelectron volts (keV), for example an energy of about 200 keV to about 400 keV, specifically about 250 keV to about 350 keV, more specifically about 300 keV.

Accordingly, as shown in FIG. 6, a plurality of impurity-doped regions 113 including the third impurity may be formed in the lower semiconductor layer 111, and the plurality of impurity-doped regions 113 are formed at a substantially equivalent depth by ion implantation so that they are disposed in substantially the same plane. In addition, in an embodiment the type of the third impurity is different from the type of the first impurity and the same as the type of the second impurity.

The acceleration energy of the ion beam may be controlled depending upon the desired depth of the impurity-doped regions 113. In an embodiment wherein the impurity-doped regions 113 are formed farther from the surface of the semiconductor substrate 110, the ion beam may have a higher acceleration energy. In another embodiment when the impurity-doped regions 113 are formed nearer to the surface, the ion beam may have a lower acceleration energy. For example, the ions may be accelerated at about 200 keV to about 400 keV, specifically about 250 keV to about 350 keV, more specifically about 300 keV in order to dispose the impurity-doped region 113 at a position of about 0.1 μm to about 9 μm, specifically about 1 μm to about 8 μm, more specifically about 3 μm to about 4 μm from the rear surface of the semiconductor substrate 110.

As shown in FIG. 1, a dielectric layer 120 is formed (e.g., disposed) on the front side of the semiconductor substrate 110. The dielectric layer 120 may be formed by plasma enhanced chemical vapor deposition (“PECVD”) of, for example, silicon nitride.

The conductive paste for the front electrode is disposed on the dielectric layer 120 in accordance with a method such as screen printing, for example, and is then dried.

Subsequently, a dielectric layer (not shown) is formed (e.g., disposed) on the rear side of the semiconductor substrate 110, and the rear electrode 150 is disposed in accordance with a method such as screen printing, for example, and is then dried.

While this disclosure has been described in connection with exemplary embodiments thereof, it is to be understood that the invention is not limited to the disclosed embodiments, but, on the contrary, is intended to cover various modifications and equivalent arrangements included within the spirit and scope of the appended claims.

What is claimed is:

1. A solar cell, the solar cell comprising:
a first semiconductor layer comprising a first impurity;
a second semiconductor layer disposed on the first semiconductor layer, the second semiconductor layer comprising a second impurity;
a first electrode electrically connected to the first semiconductor layer; and
a second electrode electrically connected to the second semiconductor layer,
wherein the first semiconductor layer comprises a plurality of impurity-doped regions comprising a third impurity, wherein a type of the third impurity is the same as a type of the second impurity.

2. The solar cell of claim 1, wherein the plurality of impurity-doped regions are discontinuously disposed.

3. The solar cell of claim 2, wherein the plurality of impurity-doped regions are disposed in substantially a same plane as each other.

4. The solar cell of claim 1, wherein the plurality of impurity-doped regions comprises a quantum well, a quantum wire, a quantum dot, or a combination comprising at least one of the foregoing.

5. The solar cell of claim 1, wherein each of the plurality of impurity-doped regions has a dimension of about 8 nanometers to about 150 nanometers.

6. The solar cell of claim 1, wherein the first semiconductor layer comprises a first surface contacting the second semiconductor layer and a second surface disposed opposite the first surface, and
the plurality of impurity-doped regions are disposed within a distance of about 10 micrometers from the second surface of the first semiconductor layer.

7. The solar cell of claim 6, wherein the plurality of impurity-doped regions are disposed at a distance of about 3 micrometers to about 4 micrometers from the second surface of the first semiconductor layer.

8. The solar cell of claim 1, wherein the plurality of impurity-doped regions absorb light having a wavelength of equal to or greater than about 1000 nanometers.

9. The solar cell of claim 1, wherein the first impurity is a p-type impurity and the second impurity is an n-type impurity.

10. The solar cell of claim 1, wherein the second impurity comprises the same type of material as the third impurity.

11. A method of manufacturing a solar cell, the method comprising:
providing a first semiconductor layer comprising a first impurity;
providing a second semiconductor layer disposed on the first semiconductor layer and comprising a second impurity;
providing a plurality of impurity-doped regions comprising a third impurity in a portion of the first semiconductor layer, wherein a type of the third impurity is the same as a type of the second impurity;
providing a first electrode electrically connected to the first semiconductor layer; and
providing a second electrode electrically connected to the second semiconductor layer.

12. The method of claim 11, wherein the providing a plurality of impurity-doped regions is performed by ion implantation.

13. The method of claim 12, wherein the providing a plurality of impurity-doped regions comprises:
providing a photosensitive layer having a plurality of openings on a surface of the first semiconductor layer; and
ion implanting the third impurity while using the photosensitive layer as a mask.

14. The method of claim 11, wherein the providing a plurality of impurity-doped regions comprises ion implanting, and the ion implanting disposes the third impurity within a distance of about 10 micrometers from the surface of the first semiconductor layer.

15. The method of claim 14, wherein the ion implanting disposes the third impurity a distance of about 3 micrometers to about 4 micrometers from a surface of the first semiconductor layer.

16. The method of claim 13, wherein the openings of the photosensitive layer have a dimension of about 8 nanometers to about 150 nanometers.

17. The method of claim 11, wherein the first impurity is a p-type impurity and the second impurity is an n-type impurity.

18. The method of claim 11, wherein the second impurity comprises the same material as the third impurity.

19. The method of claim 11, wherein the third impurity is an n-type impurity.
